(19) United States
(12) Patent Application Publication
(10) Pub. No.: US 2025/0126955 A1
(43) Pub. Date: Apr. 17, 2025

(54) LED LAMP PANEL

(71) Applicant: HUIZHOU JUFEI OPTOELECTRONICS LTD., Huizhou (CN)

(72) Inventors: Wenbo Ma, Huizhou (CN); Jianchang CHEN, Huizhou (CN); Pingru SUN, Huizhou (CN); Donghan WEI, Huizhou (CN); Meizheng XING, Huizhou (CN)

(73) Assignee: HUIZHOU JUFEI OPTOELECTRONICS LTD., Huizhou (CN)

(21) Appl. No.: 18/999,951

(22) Filed: Dec. 23, 2024

Related U.S. Application Data
(63) Continuation of application No. PCT/CN2023/102012, filed on Jun. 24, 2023.

(30) Foreign Application Priority Data
Jun. 24, 2022 (CN) 202210728844.2
Jul. 15, 2022 (CN) 202210836291.2
Aug. 30, 2022 (CN) 202211060483.5
Dec. 13, 2022 (CN) 202211601093.4

(51) Int. Cl. H10H 29/856; H01L 25/075; H10H 29/24

(52) U.S. Cl. CPC H10H 29/856; H01L 25/0753; H10H 29/24

(57) ABSTRACT

An LED lamp panel, which comprises a substrate that is provided with a circuit layer, and the circuit layer is provided with bonding pads for connecting with a plurality of LED chips; the circuit layer is provided with a first reflective layer, and the first reflective layer is provided with a plurality of window structures, which are disposed in an array, and at least one pair of bonding pads for connecting with the LED chips is distributed in each of the window structures; the LED lamp panel further comprises a second reflective layer filled between the first reflective layer and the LED chips, and the reflectivity of the second reflective layer is greater than that of the first reflective layer. The LED lamp panel provided by the present disclosure is beneficial for die bonding and has a high lighting effect, an improved process yield, and a low manufacturing cost.

### REFERENCE TO RELATED APPLICATIONS

The present application is a continuation of international application No. PCT/CN2023/102012, filed on Jun. 24, 2023, which claims the priority of CN application No. 202210728844.2, filed on Jun. 24, 2022, CN application No. 202210836291.2, filed on Jul. 15, 2022, CN application No. 202211060483.5, filed on Aug. 30, 2022, CN application No. 202211601093.4, filed on Dec. 13, 2022, the entirety of which are incorporated herein by reference.

### TECHNICAL FIELD

The present disclosure is related to the technical field of LED encapsulation, in particular to an LED lamp panel.

### BACKGROUND

In recent years, LED backlight board can realize local dimming, and the display quality has been greatly improved, which has been favored and vigorously promoted by the market. Mini LED backlight display modules and direct view products have become the mainstream solutions in future display market. In the prior art, on the one hand, since it is necessary to coat a layer of white ink on the glass substrate for a LED backlight board based on the glass substrate, and window-forming treatment is carried out at the position where the LED chip is placed to expose the bonding pad, which is convenient for welding the LED chip with the bonding pad (i.e. die bonding), the window-forming treatment of white ink will greatly affect the lighting effect of the backlight board. If the window is too large (the glass substrate will be exposed), the light emitted by the LED will be lost through the glass, while if the window is too small, the ink will cover the bonding pad to cause a bad die bonding. At the same time, the reflectivity of white ink is generally not high, and the lighting effect of the LED backlight board has been limited by the reflectivity of white ink, which leads to relatively low lighting effect of the LED backlight board, which is not beneficial for improving backlight brightness.

On the other hand, in the prior art, the lamp panel of a Mini LED backlight display module adopts a flip-chip technology structure, which is applicable for the demand of an ultra-small space, and is also applicable for encapsulated substrates of various materials. The substrate material for encapsulating the Mini LED backlight display module is generally a printed circuit board (PCB) or a glass substrate. Silicone resin or epoxy resin is generally selected as the encapsulant layer on the surface of the Mini LED backlight display module. The thermal expansion coefficient of the PCB substrate or glass substrate is (1-15)×10⁻⁶/° C., while the thermal expansion coefficient of silicone resin or epoxy resin is about (50-220)×10⁻⁶/° C. There is a large thermal expansion mismatch between the substrate and the encapsulant layer, which will make the substrate warp, with the risks of delamination, deformation, poor air tightness, chip peeling, and the like. The substrate and the encapsulant are separated due to inconsistent deformation caused by cold or heat (for example, during cold and hot impact experiments) due to a large difference in thermal expansion coefficient (the thermal expansion coefficient of the encapsulant is much larger than that of the substrate). In the prior art, the deformation is reduced by reducing the difference in thermal expansion coefficient between the substrate and the adjacent encapsulant, but the stress existing in the substrate is not eliminated, and the substrate is easily deformed. It is difficult to reduce the difference of thermal expansion coefficient between the substrate and the adjacent encapsulant, and the production cost is high.

In addition, there are many forms of LED products, and the applications of similar products in end-uses are very different, and therefore customers have various requirements for lamp beads, such as high contrast for display products, high brightness for white light products, color purity for monochromatic light, and the like. However, there are only two kinds of BT (Bismaleimide Triazine) substrates commonly used in LED encapsulation. At the same time, the internal circuit design of PCB needs to meet the process requirements in the encapsulation process, and metal functional areas need to be reserved for solid welding in the LED encapsulation process. Both the metal functional area and the primary color of BT substrate will affect the background color of LED chips after encapsulation. For example, in order to improve the contrast of display products, the black glue encapsulation will greatly reduce the brightness of the products, and at the same time, the bottom functional area cannot be completely covered. The brightness of some white light products requires high brightness, but the size of lamp beads limits the choice of larger chips, in which case the brightness improvement can only be achieved by chip suppliers to improve the luminous efficiency of LED chips, with very little and limited improvement and very high cost. In addition, the conventional encapsulation technology of MINI COB (chip on board) backlight board is that the LED flip chip is die-bonded on the circuit layer of the substrate, and then a layer of transparent protective glue is covered on the LED chip and the circuit layer to realize protection. Since the LED chip generally emits Lambert light, that is, the central part of the LED chip emits light strongly, and the two sides emit light weakly. In order to obtain a larger light emitting angle and a more uniform light emitting, in the prior art, a reflective layer is generally covered directly above the LED chip, so that the light emitted from the front of the LED chip can be reflected to the two sides. However, although a larger light emitting angle can be obtained in this way, since the reflective layer is opaque, the light emitted by the LED chip is repeatedly reflected between the reflective layer and the substrate, and the reflectivity of the substrate is less than 100%. Therefore, in the process of multiple reflections, the substrate will absorb part of the light, and the light loss is large, which obviously reduces the lighting effect and brightness of the backlight board.

In view of the above technical problems existing in the above LED lamp panel and the manufacturing thereof, it is urgent for R&D personnel to make improvements.

### SUMMARY

An object of the present disclosure is to overcome at least one of the shortcomings of the prior art by providing an LED lamp panel, which is beneficial for die bonding, which improves the lighting effect and the process yield and has a low manufacturing cost.

The technical solution of the present disclosure is that an LED lamp panel includes a substrate and an LED chip; a circuit composite layer is disposed on the substrate, and the circuit composite layer is provided with bonding pads for connecting with the LED chip.

As a further improvement of the technical solution, a first reflective layer is disposed on the circuit composite layer, and the first reflective layer is provided with a plurality of window structures, each window structure having at least one pair of the bonding pads in a corresponding area; the LED chip is disposed in the window structure and connected to the bonding pads in the corresponding window structure, and an accommodating area is formed between the outer periphery of the LED chip and the inner periphery of the window structure; the LED lamp panel further includes a second reflective layer filled in the accommodating area.

As a further improvement of the technical solution, the circuit composite layer includes a circuit layer and a reflective layer that is disposed on the circuit layer and has window structures, each of the window structures having at least one pair of the bonding pads in the corresponding area; and the LED chip is disposed in the window structure and connected to the bonding pads in the corresponding window structure; and the LED lamp panel further includes a first encapsulant layer that is disposed on one side of the substrate, covers the LED chip and the circuit composite layer and allows the light emitted by the LED chip to pass through; and the LED lamp panel further includes a second encapsulant layer disposed on the other side of the substrate for partially or completely offsetting the stress generated by the first encapsulant layer on the substrate.

As a further improvement of the technical solution, the circuit composite layer includes a circuit layer and a reflective layer that is disposed on the circuit layer and has window structures, each of the window structure having at least one pair of the bonding pads in the corresponding are; and the LED chip is disposed in the window structure and connected to the bonding pads in the corresponding window structure; and the LED chip is located in the window structure and connected to the circuit layer; and the LED lamp panel further includes a second reflective layer, which is filled in the window structure and is respectively connected with the LED chip and the reflective layer; and the second reflective layer has a color identical with that of the reflective layer.

As a further improvement of the technical solution, the second reflective layer is made of resin, and reflective particles are dispersed in the second reflective layer.

As a further improvement of the technical solution, the second reflective layer is formed by glue dispensing in the window structure.

As a further improvement of the technical solution, the LED chip is a flip chip, and a gap exists between a side of the LED chip facing the substrate and the substrate; the second reflective layer includes a side reflective part connected with the outer periphery of the LED chip and a bottom reflective part filled in the gap.

As a further improvement of the technical solution, the surface of the bonding pad is provided with a solder paste layer used for connecting with the LED chip, and the second reflective layer covers the periphery of the joint between the LED chip and the solder paste layer.

As a further improvement of the technical solution, the top surface of the first reflective layer is between the bottom surface and the top surface of the LED chip, and the top surface of the second reflective layer is not higher than the top surface of the first reflective layer.

As a further improvement of the technical solution, the second reflective layer has a reflectivity greater than that of the first reflective layer.

As a further improvement of the technical solution, the first reflective layer is made of white ink.

As a further improvement of the technical solution, the value of the thickness of the first reflective layer ranges from 20 μm to 80 μm.

As a further improvement of the technical solution, the dimensions of the window structure satisfy the following relationship:

Bx<Px, By<Py;
where Bx represents the largest dimension of the window structure in the transverse direction, By represents the largest dimension of the window structure in the longitudinal direction, Px represents the transverse spacing between two adjacent LED chips, and Py represents the longitudinal spacing between two adjacent LED chips.

As a further improvement of the technical solution, the window structure is a rectangular through hole, and the length dimension of the rectangular through hole is greater than or equal to ≥2 mm.

As a further improvement of the technical solution, a plurality of LED chips are provided, and the LED lamp panel further includes a plurality of reflection patterns; and the second reflective layer covers the substrate and the LED chips, and the reflection patterns are disposed on the upper surface of the second reflective layer; and the reflection pattern includes a plurality of reflection units disposed at intervals, and air gaps are formed between the reflection units; and the reflection units include resin and reflection particles dispersed in the resin, and the density of the reflection particles in the central area of the reflection pattern is greater than that in the peripheral region of the reflection pattern; and the first reflective layer is disposed on a side of the circuit composite layer connected with the LED chip, and a side of the second reflective layer covers the first reflective layer and the LED chips.

As a further improvement of the technical solution, in one of the reflection patterns, the area of the air gap accounts for 20% to 80% of the area of the outline of the reflection pattern;
and/or the reflection pattern has a thickness of 10 μm to 60 μm.

As a further improvement of the technical solution, the reflection units include a reflection ring located in the central area of the reflection pattern.

As a further improvement of the technical solution, the reflection units include a plurality of reflection rings disposed concentrically, and there is a gap between adjacent reflection rings.

As a further improvement of the technical solution, the periphery of the reflection ring is provided with reflection points, and the distribution density of the reflection points decreases with the distance from the center of the reflection pattern.

As a further improvement of the technical solution, the reflection units include a plurality of reflection points around the center of the reflection pattern, and the areas of the reflection points decrease with the distance from the center of the reflection pattern.

As a further improvement of the technical solution, the reflectivity of the reflection units in the central area of the reflection pattern is greater than that of the reflection units in the peripheral area of the reflection pattern.

As a further improvement of the technical solution, the reflection units in the central area of the reflection pattern contain titanium dioxide particles, and the reflection units in the peripheral area of the reflection pattern contain silicon dioxide particles.

As a further improvement of the technical solution, the reflection pattern is formed by screen printing, and the sidewall of the reflection units are provided with demoulding inclined planes.

As a further improvement of the technical solution, the present disclosure further includes an optical film disposed above the second reflective layer, wherein diffusion patterns are printed on the surface of the optical film, and the diffusion patterns of the optical film and the reflection patterns are disposed in a staggered manner.

As a further improvement of the technical solution, the thickness of the first encapsulant layer is greater than that of the second encapsulant layer, the first encapsulant layer has a first thermal expansion coefficient, and the second encapsulant layer has a second thermal expansion coefficient greater than the first thermal expansion coefficient.

As a further improvement of the technical solution, the first encapsulant layer and the second encapsulant layer are made of the same material, which is epoxy resin or silicone resin.

As a further improvement of the technical solution, the first encapsulant layer is provided with inorganic light-transmitting particles for adjusting the thermal expansion coefficient thereof.

As a further improvement of the technical solution, the inorganic light-transmitting particles settle in the first encapsulant layer, so that the content of the inorganic light-transmitting particles gradually decreases along the direction away from the substrate.

As a further improvement of the technical solution, the particle size of the inorganic light-transmitting particles ranges from 50 nm to 5 μm.

As a further improvement of the technical solution, the inorganic light-transmitting particles are at least one of silica powder or alumina powder.

As a further improvement of the technical solution, the thickness of the first encapsulant layer ranges from 150 μm to 400 μm; and/or the thickness of the second encapsulant layer ranges from 20 μm to 200 μm.

As a further improvement of the technical solution, the first encapsulant layer is in direct contact with the substrate through the window structure.

As a further improvement of the technical solution, an upper end of the second reflective layer and an upper end of the reflective layer are both lower than an upper end of the LED chip.

As a further improvement of the technical solution, the thickness of the reflective layer ranges from 20 μm to 50 μm.

As a further improvement of the technical solution, the LED lamp panel further includes encapsulant layers disposed on the top of the reflective layer and the top of the second reflective layer and covering the LED chips.

As a further improvement of the technical solution, the second reflective layer and the encapsulant layers are made of a same material, which is epoxy resin or silica gel.

As a further improvement of the technical solution, the colors of the second reflective layer and the reflective layer are white or black.

As a further improvement of the technical solution, the second reflective layer is made of colored ink or colored colloid with a viscosity less than 2000 mPa·s.

As a further improvement of the technical solution, the inner sidewall of the window structure or the circuit layer has a fillet or chamfer structure.

As a further improvement of the technical solution, there are a plurality of window structures, and one or more LED chips are wire-bonded chips or flip chips and are fixed in respective window structures.

The LED lamp panel provided by the present disclosure includes a substrate, wherein the substrate is provided with a circuit layer, and the circuit layer is provided with bonding pads for connecting with a plurality of LED chips. The circuit layer is provided with a first reflective layer, the first reflective layer is provided with a plurality of window structures arranged in a form of an array, and at least one pair of bonding pads for connecting with the LED chips is distributed in each window structure. The LED lamp panel further includes a second reflective layer filled between the first reflective layer and the LED chips, and the reflectivity of the second reflective layer is greater than that of the first reflective layer.

The LED lamp panel provided by the present disclosure is beneficial for die bonding, improves the lighting effect, improves the process yield and has low manufacturing cos. By disposing the first encapsulant layer on one side of the substrate to cover the LED chip and the circuit layer, the first encapsulant layer allows the light emitted by the LED chip to pass through; the second encapsulant layer is disposed on the other side of the substrate, so as to partially or completely offset the stress generated by the first encapsulant layer on the substrate, reduce the warpage and deformation of the substrate caused by stress, and improve the delamination, deformation, poor air tightness, and the like of the lamp panel after encapsulation, with a low production cost. Except that the LED chip is exposed out of the substrate, the second reflective layer with the same color as the first reflective layer is respectively connected with the LED chip and the first reflective layer, and the second reflective layer can completely cover the rest area of the substrate; that is, the second reflective layer is filled in the window structure and can also cover the surrounding area of the LED chip, so that the color consistency of the encapsulated substrate surface can be effectively improved, and different colored glues can be applied to improve the luminous brightness or contrast according to different occasions. For example, when the LED encapsulation structure is used for white LED products, the white glue layer can enhance the reflective effect of the area around the LED chip and effectively improve the white brightness; when the LED encapsulation structure is used in RGB-LED direct view products, the black glue layer can reduce the reflection of the area around the RGB-LED chip, reduce the reflection effect and effectively improve the contrast; when it is used for monochromatic LED products, the use of a second reflective layer of a corresponding color system can prevent the light emitted by LED chips from mixing with other miscellaneous colors and ensure the purity of light.

### BRIEF DESCRIPTION OF DRAWINGS

In order to explain the technical solution in the embodiment of the present disclosure more clearly, the drawings to be used in the embodiment will be briefly introduced below. Obviously, the drawings in the following description are only some embodiments of the present disclosure, and other drawings can be obtained according to these drawings without creative work for those skilled in the art. In the present disclosure:

FIG. 1 is a schematic structural diagram of a substrate in an LED lamp panel provided in Embodiment 1 of the present disclosure;

FIG. 2 is a schematic structural diagram of a printed circuit layer on a substrate in an LED lamp panel provided in Embodiment 1 of the present disclosure;

FIG. 3 is a schematic structural diagram of an LED lamp panel provided in Embodiment 1 of the present disclosure, in which a first reflective layer is coated on a circuit layer;

FIG. 4 is a structural schematic diagram of an LED lamp panel provided in Embodiment 1 of the present disclosure, in which a first reflective layer is provided with a window structure;

FIG. 5 is a schematic structural diagram of an LED chip welded to a pad in an LED lamp panel provided in Embodiment 1 of the present disclosure;

FIG. 6 is a schematic structural diagram of an LED lamp panel provided by Embodiment 1 of the present disclosure, in which a second reflective material is filled in an accommodating area;

FIG. 7 is a schematic structural diagram of an LED lamp panel provided in Embodiment 1 of the present disclosure;

FIG. 8 is a top view of an LED lamp panel provided in Embodiment 1 of the present disclosure;

FIG. 9 is another top view of an LED lamp panel provided in Embodiment 1 of the present disclosure;

FIG. 10 is a schematic sectional view of an LED lamp panel provided in Embodiment 2 of the present disclosure;

FIG. 11 is a schematic plan view of an LED lamp panel (the reflection area near the center of the LED chip is dense) provided in Embodiment 2 of the present disclosure;

FIG. 12 is a schematic plan view of an LED lamp panel (the reflection pattern is provided with demoulding inclined planes) provided in Embodiment 2 of the present disclosure;

FIG. 13 is a schematic plan view of an LED lamp panel (the central reflection area is circular) provided in Embodiment 2 of the present disclosure;

FIG. 14 is a schematic plan view of an LED lamp panel (the size of the reflection area near the center of the LED chip is large) provided by Embodiment 2 of the present disclosure;

FIG. 15 is a schematic sectional view of an LED lamp panel provided in Embodiment 2 of the present disclosure with an optical film;

FIG. 16 is a schematic plan view of an LED lamp panel provided by Embodiment 2 of the present disclosure with an optical film;

FIG. 17 is a schematic structural diagram of an LED lamp panel provided in Embodiment 3 of the present disclosure, in which a first encapsulant layer is disposed on one side of a substrate;

FIG. 18 is a schematic structural diagram of an LED lamp panel provided in Embodiment 3 of the present disclosure, in which a second encapsulant layer is disposed on the other side of the substrate;

FIG. 19 is a schematic diagram of an LED lamp panel provided in Embodiment 3 of the present disclosure, in which inorganic light-transmitting particles settle in a first encapsulant layer;

FIG. 20 is a schematic structural diagram of an LED lamp panel provided in Embodiment 4 of the present disclosure;

FIG. 21 is a schematic structural view of an LED lamp panel provided in another Embodiment of Embodiment 4 of the present disclosure;

FIG. 22 is another structural schematic diagram of an LED lamp panel provided in Embodiment 4 of the present disclosure;

FIG. 23 is a schematic structural view of an LED lamp panel provided in another embodiment of Embodiment 4 of the present disclosure; and

FIG. 24 is a partial enlarged view at a in FIG. 23.

### DESCRIPTION OF EMBODIMENTS

In order to make the purpose, technical solution and advantages of the present disclosure more clear, the present disclosure will be further described in detail with the attached drawings and examples. It should be appreciated that the specific embodiments described here are only for explaining the present disclosure, and are not intended to limit the present disclosure.

It should be noted that the terms “dispose” and “connect” should be broadly understood, for example, they can be directly disposed and connected, or indirectly disposed and connected through the central component and the central structure.

In addition, if there are expressions indicating the orientation or position relationship such as “vertical,” “horizontal,” “length,” “width,” “thickness,” “top,” “bottom,” “front,” “back,” “left,” “right,” “vertical,” “horizontal,” “top,” and “bottom” in the embodiment of the present disclosure, they are based on the orientation or position relationship shown in the drawings or the conventional placing state or use state, rather than indicating or implying that the referred structure, feature, device or element must have a specific orientation or positional relationship, nor must it be constructed and operated in a specific orientation, therefore they cannot be construed as limiting the present disclosure. In the description of the present disclosure, unless otherwise specified, “plural” means two or more.

Each specific technical feature and each embodiment described in the specific embodiment can be combined in any suitable way without contradiction. For example, different embodiments can be formed by the combination of different specific technical features/embodiments. In order to avoid unnecessary repetition, various possible combinations of each specific technical feature/embodiment in the present disclosure are not explained separately.

An LED lamp panel provided by an embodiment of the present disclosure includes a substrate and an LED chip. A circuit composite layer is disposed on the substrate, and the circuit composite layer is provided with a bonding pad for connecting with the LED chip; a first reflective layer is disposed on the circuit composite layer, and the first reflective layer is provided with a plurality of window structures, and each window structure has at least one pair of bonding pads in the corresponding area; the LED chip is disposed in the window structure and connected to the bonding pad in the corresponding window structure, and an accommodating area is formed between the outer periphery of the LED chip and the inner periphery of the window structure; the LED lamp panel further includes a second reflective layer filled in the accommodating area; alternatively,
the circuit composite layer includes a circuit layer and a reflective layer that is disposed on the circuit layer and has a window structure, and each window structure has at least one pair of bonding pads in the corresponding area; the LED chip is disposed in the window structure and connected to the bonding pad in the corresponding window structure; the LED lamp panel further includes a first encapsulant layer that is disposed on one side of the substrate and covers the LED chip and the circuit composite layer, and allows the light emitted by the LED chip to pass through; the LED lamp panel further includes a second encapsulant layer that is disposed on the other side of the substrate and used for partially or completely offsetting the stress generated by the first encapsulant layer on the substrate; alternatively,
the circuit composite layer includes a circuit layer and a reflective layer that is disposed on the circuit layer and has a window structure, and each window structure has at least one pair of bonding pads in the corresponding area; the LED chip is disposed in the window structure and connected to the bonding pad in the corresponding window structure; the LED chip is located in the window structure and connected to the circuit layer; the LED lamp panel further includes a colored glue layer, which is filled in the window structure, and is respectively connected with the LED chip and the reflective layer, and the color of the colored glue layer is the same as that of the reflective layer, which is beneficial for die bonding, improves the lighting effect, has a high preparation efficiency and a low manufacturing cost. The present disclosure will be further described and illustrated with reference to specific examples.

### Embodiment 1

Please refer to FIG. 7, an LED lamp panel provided by an embodiment of the present disclosure includes a substrate and LED chips 1. In this embodiment, the substrate is a glass substrate 6, and a circuit composite layer 3 is disposed on the substrate. A plurality of LED chips 1 are disposed on the surface of the glass substrate 6 and are electrically connected with the circuit composite layer 3. In an embodiment, the circuit layer 3 is at least a pair of pads, and a plurality of LED chips are respectively connected with the pads. The circuit layer or pad layer 3 is provided with a first reflective layer 4, which covers the circuit layer 3 and has a plurality of window structures 41. These window structures 41 penetrate the holes of the first reflective layer 4 to expose the underlying pads. The LED chips 1 are disposed in these window structures 41 and connected to the pads corresponding to the window structures 41. In this embodiment, all the window structures 41 are disposed in a form of an array, and the windo area of each of the window structures 41 is larger than the projection area of the LED chips 1 on the glass substrate 6, which exposes the position on the surface of the glass substrate 6 where the LED chips 1 need to be soldered, thereby facilitating the LED chips 1 to be placed in the window structures 41 The design of disposing the window structures 41 allows the bonding pads to be exposed, so as to prevent the bonding pads from being covered by the first reflective layer 4, and facilitate the welding of the LED chip 1 with the corresponding bonding pad. If the gap between the window structure 41 and the LED chip 1 is too small, it is inconvenient for installation; otherwise if the gap is too large, it is easy to leak light, which will affect the lighting effect and the process yield.

Please refer to FIG. 7, in this embodiment, the LED lamp panel further includes a second reflective layer 5. Since the size of the window structure 41 is larger than the external dimension of the LED chip 1, an accommodating area is formed between the outer periphery of the LED chip 1 and the inner periphery of the window structure 41. This embodiment includes a second reflective layer 5, which is filled in the accommodating area, that is, the second reflective layer 5 is located in the window structure 41, above the circuit layer 3 and on the periphery of the LED chip 1, and is closely attached to the outer periphery of the LED chip 1, and the second reflective layer 5 is closely attached to the inner periphery of the window structure 41. The size of the window structure 41 is larger than that of the LED chip 1, so that the LED chip 1 can be easily placed in the window structure 41, with a high manufacturing efficiency is high, a low manufacturing cost is low, which facilitates in ensuring the yield of die bonding; moreover, by filling second reflective layer 5 formed by filling, the accommodating area can be well filled, and the light leakage gap can be avoided. The LED lamp panel provided by the embodiment of the present disclosure is beneficial for die bonding, improves the lighting effect, has a high preparation efficiency and a low manufacturing cost.

Further, the reflectivity of the second reflective layer 5 is greater than that of the first reflective layer 4, and the reflectivity of the second reflective layer 5 is higher than that of the first reflective layer 4. The second reflective layer 5 with higher reflectivity reflects more effective rays and has higher luminous efficiency, that is, the lighting effect is improved.

Further, the height of the light-emitting surface of the LED chip 1 is greater than or equal to the height of the first reflective layer 4, and the height of top surface of the second reflective layer 5 is smaller than or equal to the height of the top surface of the first reflective layer 4. The thickness of the first reflective layer 4 may range from 20 μm to 80 μm. In the specific application, the second reflective layer 5 is filled in the accommodating area between the LED chip 1 and the first reflective layer 4, that is, in the window structure 41. The top surface of the second reflective layer 5 may be lower than the top surface of the first reflective layer 4, or kept flush with the top surface of the first reflective layer 4. In this embodiment, the second reflective layer 5 is formed by solidification of a colloid, which has certain fluidity and good filling effect, and avoids the occurrence of glue shortage.

As shown in FIG. 7, The thickness of the first reflective layer 4 is a and the thickness of the second reflective layer 5 is c. In order to prevent colloid from overflowing to the upper surface of the first reflective layer 4, it is necessary to control the amount of the glue forming the second reflective layer 5 so that the thickness c of the second reflective layer 5 is less than or equal to the thickness a of the first reflective layer 4, thereby avoiding the colloid of the second reflective layer 5 from overflowing to the first reflective layer 4, which is beneficial for ensuring the consistency of lighting effect of the LED lamp panel. The value of a may range from 20 μm to 80 μm, preferably from 25 μm to 60 μm, more preferably from 50 μm to 60 μm.

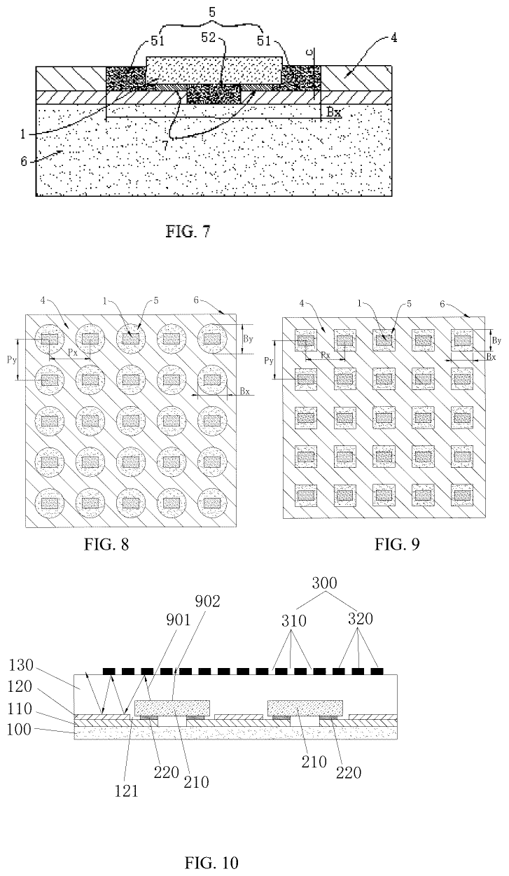

Please refer to FIG. 8, Bx represents the largest dimension of the window structure in the transverse direction, By represents the largest dimension of the window structure in the longitudinal direction, Px represents the transverse spacing between two adjacent LED chips 1, and Py represents the longitudinal spacing between two adjacent LED chips 1. The dimensions of the window structure 41 satisfy the following relationships: Bx<Px, By<Py. That is, the lateral distance Px between two adjacent LED chips 1 is greater than the lateral width Bx of the window structure 41, while the longitudinal distance Py between two adjacent LED chips 1 is greater than the longitudinal width By of the window structure 41. In an embodiment, the window structure 41 is a rectangular slot, and its largest dimension is the length of the rectangular, as shown in FIG. 9, with the Pitch between the centers of two adjacent LED chips 1 being p, and the transverse center distance between two adjacent LED chips 1 being Px and the longitudinal center distance being Py. The maximum transverse dimension of the window structure 41 is Bx and the maximum longitudinal dimension thereof is By, wherein the dimensions of the window structure 41 satisfy Bx<Px, By<Py. The length dimension of the rectangle Bx is ≥2 mm, preferably Bx is ≥3 mm. In another embodiment, as shown in FIG. 8, the window structure 41 may also be in the shape of a circular hole, in which case its largest dimension is its diameter, and the diameters are all smaller than Px and Py. It can be ensured that the window opening area of the window structure 41 is larger than the projection area of the LED chip 1 on the glass substrate 6, which is beneficial for exposing the position on the surface of the glass substrate 6 where the LED chip 1 needs to be soldered. The LED chip 1 may be centrally disposed in the window structure 41, and adjacent window structures 41 are not connected, which is beneficial for production and cost control.

Please refer to FIG. 7, further, the LED chip 1 can be a flip chip, and there is a gap between the side of the LED chip 1 facing the glass substrate 6 and the glass substrate 6. The second reflective layer 5 includes a side reflective part 51 and a bottom reflective part 52. The side reflective part 51 is joint with the periphery of the LED chip 1, and the bottom reflective part 52 is filled in the gap and joint with the bottom surface of the LED chip 1.

The surface of the bonding pad is provided with a solder paste layer 7, and the metal solder paste of the solder paste layer 7 is gray and absorbs blue light. The LED chip 1 is connected to the circuit layer or the bonding pad 3 through the solder paste layer 7, forming the above-mentioned gap filled by the bottom reflective part 52. The solder paste layer 7 is used to connect with the LED chip 1. Specifically, the solder paste is printed on the bonding pad, and the LED chip 1 is soldered on the bonding pad, that is, die bonding is completed.

The height of the light-emitting surface of the LED chip 1 is greater than or equal to the height of the first reflective layer 4. In this embodiment, the height of the top surface of the first reflective layer 4 should not be higher than the top surface of the LED chip 1 to block the light source, nor should it be lower than the bottom surface of the LED chip 1 to expose the solder paste layer 7. In this embodiment, the LED chip 1 is connected to the circuit layer or the bonding pad through a solder paste layer 7 (metal solder paste), and the metal solder paste is gray, and the bottom reflective part 52 located at the bottom of the LED chip 1 may be coated on the metal solder paste layer 7, so that blue light can be prevented from being absorbed by the solder paste layer 7.

The first reflective layer 4 may be made of white ink, while the second reflective layer 5 is made of silica gel or silicone resin, and reflective particles are dispersed therein. In specific application, the second reflective layer 5 contains TiO₂ reflective particles, BaSO₄ reflective particles, or a combination thereof, that is, a certain amount of reflective particles are mixed into the glue material, which is beneficial for further improving the reflectivity of the second reflective layer 5. The LED lamp panel, the first reflective layer may be composed of white ink and white glue, wherein both white glue and white ink can be used as reflective materials. The white ink has a low cost, but a low reflectivity and a poor fluidity, and is applicable for large-area printing. In this embodiment, the first reflective layer 4 is made of white in. White glue is expensive, but it has high reflectivity and good fluidity, and can be used for local gap dispensing in the prior art, therefore in this embodiment, the second reflective layer 5 is made of white glue.

The reflectivity of the first reflective layer 4 is smaller than or equal to 93%, while the reflectivity of the second reflective layer 5 is greater than or equal to 98%, which solve all of the problems of difficult die bonding, low lighting effect and high cost. The LED lamp panel provided by the present disclosure realizes easy die-bonding, improves the lighting effect at the same time, has high efficiency and low cost, ensures easy die bonding and high lighting effect while taking the cost into consideration, has strong operability in actual production, and thus has a high market application value.

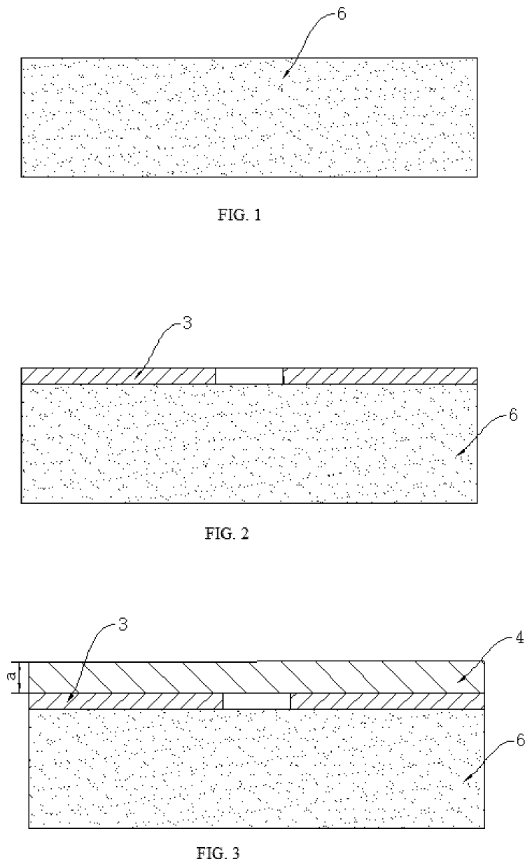

Referring to FIGS. 1 to 9, an embodiment of the present disclosure also provides a manufacturing method of an LED lamp panel, which is used for manufacturing the LED lamp panel, and includes the following steps:

Step 1, as shown in FIG. 1, a substrate is prepared. In this embodiment, a glass substrate 6 is used, which has a good stability and a low cost.

Step 2, as shown in FIG. 2, a circuit layer 3 is provided on the substrate. Specifically, the circuit layer 3 is printed on the substrate, and is connected with a plurality of LED chips 1.

Step 3, as shown in FIG. 3, a first reflective layer 4 made of a first reflective material is provided on the circuit layer 3. In this embodiment, white ink is printed on the circuit layer 3 to form the first reflective layer 4.

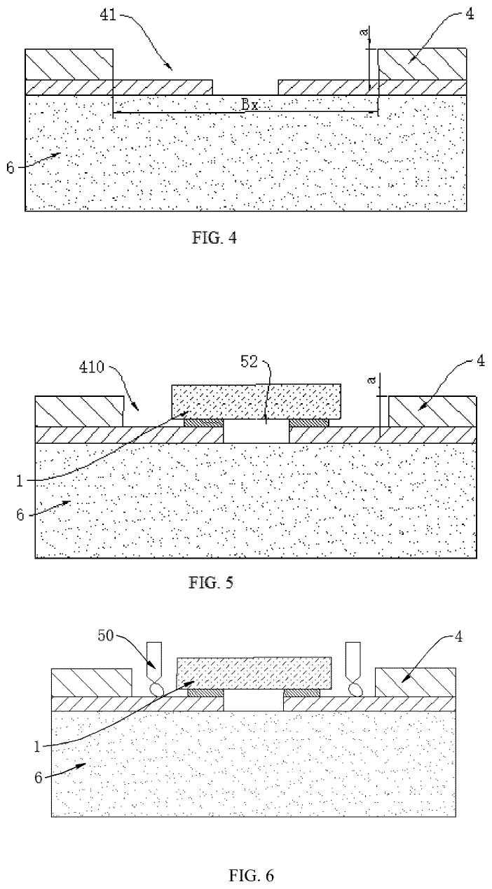

Step 4, as shown in FIG. 4, the first reflective layer 4 is provided with a plurality of window structures 41, so that there is at least one pair of bonding pads in the area of each of the window structures 41. Specifically, in this embodiment, the window structure 41 is formed by an exposure etching process. The first reflective layer 4 is provided with a plurality of window structures 41 disposed in a matrix. In this embodiment, the window structures 41 are rectangular slots (as shown in FIG. 7), and in another embodiment, the window structures 41 can also be circular holes (as shown in FIG. 8).

Step 5, as shown in FIG. 5, the LED chip 1 is disposed in the window structure 41, and the LED chip 1 is connected with the bonding pads. Specifically, the bonding pads corresponding to the same LED chip 1 are also located in the window structure 41, that is, the LED chips 1 located in the window structure 41 are connected with the corresponding pads, and two or more LED chips 1 can also be disposed in each window structure 41.

Step 5, as shown in FIG. 6, a second reflective material 50 is filled in the window structure 41, and the second reflective material 50 is located between the first reflective layer 4 and the LED chip 1 to form a second reflective layer 5, as shown in FIG. 7. In this embodiment, the reflectivity of the second reflective material 50 is greater than that of the first reflective material. Specifically, in this embodiment, white glue is used as the second reflective material 50.

An embodiment of the present disclosure provides an LED lamp panel and a manufacturing method thereof. The circuit layer 3 is provided with a first reflective layer 4, which is provided with a plurality of window structures 41. The LED chip 1 is disposed in the window structures 41 and connected to the bonding pads corresponding to the window structure 41. An accommodating area is formed between the outer periphery of the LED chip 1 and the inner periphery of the window structure 41. Filling the accommodating area with the second reflective layer 5 with a high reflectivity is beneficial for die bonding, and the manufacturing cost is low. The reflectivity of the second reflective layer 5 is greater than that of the first reflective layer 4, so that the lighting effect can be improved. The LED lamp panel and the manufacturing method thereof provided by the present disclosure are not only beneficial for die bonding, but also improve the lighting effect, improve the process yield and have low manufacturing cost.

### Embodiment 2

The LED lamp panel provided by the embodiment of the present disclosure further includes a plurality of reflection patterns. As shown in FIG. 10, an LED lamp panel provided by an embodiment of the present disclosure includes a substrate 6, a circuit layer 3 and a plurality of LED chips 1. The circuit layer 3 is disposed on the substrate 6, and the LED chips 1 are disposed on the circuit layer 3 and are electrically connected with the circuit layer 3. The LED lamp panel further includes an encapsulant layer 130 and a plurality of reflection patterns 300. The encapsulant layer 130 covers the substrate 6 and the plurality of LED chips 1, and the reflection patterns 300 are disposed on the upper surface of the encapsulant layer 130. The light emitting surfaces of the plurality of LED chip 1 face the reflection patterns 300, and the reflection patterns 300 include a plurality of reflection units 320 arranged at intervals. Air gaps 310 are formed between the reflection units 320. The reflection units 320 are composed of resin and contain reflective particles dispersed therein. In this embodiment, the density of the reflective units in the central area of the reflection pattern 300 is greater than that of the reflective units in the peripheral area, and part of the light emitted by the light emitting surface of the LED chip 1 can be reflected.

As described in Embodiment 1, in this application, a first reflective layer 4 is further included, which, in this embodiment, can be a white glue layer, and can contain reflective particles dispersed thereinthe first reflective layer 4. The first reflective layer 4 is disposed on the side of the circuit layer 3 connected with the LED chip 1, and the encapsulant layer 130 covers the first reflective layer 4 4 and the plurality of LED chips 1.

In this embodiment, the reflection pattern 300 includes reflection units 320 and an air gap 310. The reflection units 320 are the reflection area for reflecting light, and the air gap 310 is the hollowed-out area for light to pass through. Please refer to FIG. 10, part of the light 901 emitted by the LED chips 1 is directed to the reflection units 320, and the other part of light 902 is directly emitted from the air gap 310. The light directed to the reflection units 320 is reflected by the reflection units 320 to form reflected light. Part of the reflected light is reflected by the reflective layer and then emitted from the hollowed-out area and the side of the LED chip 1. In view of the characteristics of strong light emission in the central part of the LED chip 1 and weak light emission in the peripheral part.

Iin this embodiment, the proportion and distribution of the reflection units 320 and the air gaps can be modulated to make the density of the reflection units in the central area of the reflection pattern 300 greater than that of the reflection units in the peripheral area. Part of the light emitted by the LED chip 1 can be directly emitted from the front face through the hollowed-out area and part of the light is reflected by the reflection area, which can effectively modulate the brightness of the light emitting surface of the LED chips 1, and ensure the lighting effect and brightness of the backlight board. Meanwhile, under the local reflection of the reflection patterns 300, part of the light is reflected to the area on the side of the LED chip 1, so that the light-emitting angle of the LED chip 1 after passing through the encapsulant layer 130 is increased, the brightness of the LED chip 1 at the peripheral area is improved, the light-emitting uniformity of the light-emitting board is improved, and the application effect is good.

In an embodiment, the LED chip 1 of this application may be a MINI LED flip-chip, which is connected to the circuit layer 3 through the a solder paste layer 7. Specifically, the first reflective layer 4 may be provided with a window structure 410 at a position corresponding to the LED chip 1, and the encapsulant layer 130 may be filled in the window structure 410, that is, the gap between the first reflective layer 4 and the LED chip 1.

In an embodiment, the reflection pattern 300 is disposed on the encapsulant layer 130, that is, on the opposite side of the encapsulant layer 130 in contact with the LED chip 1. In another embodiment, the reflection pattern 300 is embedded in the encapsulant layer 130, that is, the reflection pattern 300 can be sandwiched in the encapsulant layer 130 to form a sandwich structure. The reflection pattern 300 can be protected by the encapsulant layer 130 to prevent accidental damage. In an embodiment, the reflection pattern 300 can be formed on the surface of the encapsulant layer 130 by stencil screen printing. The process is simple and reliable, and the hollowing-out size and hollowing-out ratio can be accurately controlled, with a good product consistency, a high production efficiency and a low cost.

Specifically, in the reflection patterns 300, the area of the air gap 310 (a hollowed-out area) can account for 20% to 80% of the area of the outline of the reflection pattern 300, which is beneficial for ensuring the lighting effect and light-emitting uniformity. In specific applications, the area of the air gap 310 can account for 30% to 60% of the area of the outline of the reflection pattern 300, which can improve the lighting effect and brightness of the backlight board and ensure the uniformity of light emission of the panel. In specific applications, the thickness of the reflection pattern 300 can be 10 μm to 60 μm, which has a good reflection effect and a low application cost.

In specific applications, the reflection pattern 300 can be made of white glue, that is, the white glue is silk-printed into the reflection pattern 300 with a hollowed-out area. The white glue may be white silicone.

Alternatively, the reflection pattern 300 may include white glue or white silicone and reflective particles embedded in the white glue, and the reflective particles may be titanium dioxide reflective particles or/and silicon dioxide reflective particles to improve the reflective efficiency of light. In this embodiment, the reflectivity of the reflection area of the reflection pattern 300 reaches or exceeds 88%.

In an embodiment, as shown in FIG. 10, the reflection units 320 may include a reflection area with a point structure, a block structure, a linear structure, a grid structure or a ring structure. In another embodiment, as shown in FIG. 13, the reflection units 320 can be in the shape of a dot, a ring (, a polygon, a polygonal ring (a hollowed-out polygon), a straight line, a wavy line, a folded line, etc., and the reflection area can also be in the shape of a rectangular grid, a rhombic grid, and the like.

Please refer to FIG. 10, the density of the reflection area near the center of the LED chip 1 can be greater than that of the reflection area far away from the center of the LED chip 1, that is, the reflection units in the central part of the reflection area are relatively dense, while those in the peripheral areas are relatively sparse, which can effectively modulate the brightness above the LED chip 1, reinforce the brightness of the periphery of the LED chip 1, and make the lighting effect uniform.

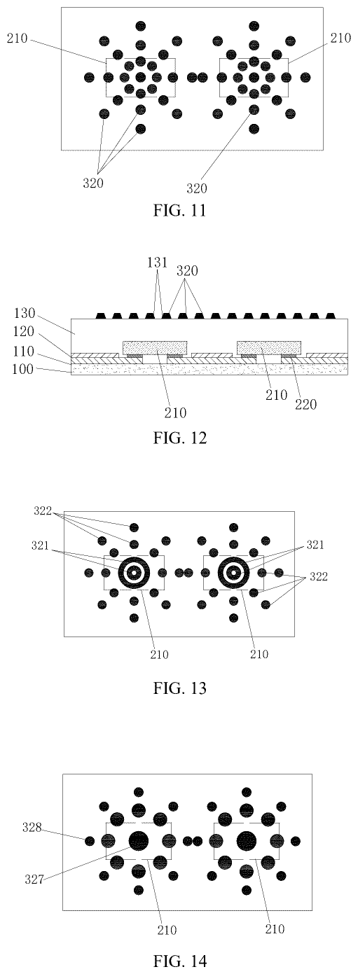

As shown in FIG. 11, the density of the hollowed-out area near the center of the LED chip 1 can be less than that of the hollowed-out area far away from the center of the LED chip 1, that is, the air gaps are relatively sparse in the center (referring to the center of the LED chip 1) and relatively dense on the periphery, which can effectively modulate the brightness above the LED chip 1, reinforce the brightness on the periphery of the LED chip 1, and make the lighting effect uniform.

Of course, in some embodiments, the air gaps may also be set randomly or uniformly.

Specifically, there are one or at least two LED chips 1, and the reflection areas include a central reflection area and peripheral reflection areas. The central reflection area is disposed right above each LED chip 1, and the peripheral reflection areas are disposed at the periphery of the central reflection area. The density of the reflection areas in the central reflection area is greater than that of the peripheral reflection areas, which is beneficial for modulating the brightness above the LED chip 1, reinforce the brightness around the LED chip 1, and make the lighting effect uniform.

As an optional solution of the reflection pattern 300, as shown in FIG. 13, the reflection units 320 include a plurality of concentrically disposed reflection rings 321, and there are spacings between adjacent reflection rings 321, forming air gaps 310. The shape of the reflection ring 321 may be a circular ring or a polygonal ring. The spacings between adjacent reflection rings 321 can be equal, or may be designed such that the spacing near the center of the reflection ring group is smaller while the spacing far away from the center is larger. The shape of the reflection rings 321 can be annular, and the larger the radius of the reflection ring 321, the larger the spacing between adjacent reflection ring 321, so as to adapt to the characteristics of the LED chip 1 with strong light emission at the center and weak light emission at the edge. After the reflection by the reflection pattern 300, the light is more uniform, so that the brightness above the LED chip 1 is modulated, the brightness of the periphery is reinforced, and the uniformity of lighting effect is improved.

Specifically, the dotted box shows the LED chips 1 (LED chips), and each LED chip 1 is provided with the reflection ring groups 321, 322 above the light-emitting direction, and the centers of the reflection ring groups 321, 322 correspond to the centers of the LED chips 1, so that the brightness of the LED chip 1 can be well modulated.

In an embodiment, the periphery of the reflection ring can be provided with a scattered reflection structure, which may be in the shape of a dot, a strip or a ring or other shapes, that is, the scattered reflection structure can be a reflection point. In specific applications, the scattered reflection structures may be uniformly distributed, or the density decreases with the distance from the center of the reflection pattern 300, so as to reinforce the brightness of the periphery of the LED chip 1 and make the uniformity of lighting effect better. In specific applications, the scattered reflection structure can be reflection points 322 that are distributed in the circumferential direction at intervals. The reflection points 322 can be circular or polygonal, and they can be evenly spaced along one or at least two concentric circles (concentric with the reflection ring 321). As the increase of the radius of the concentric circles, the spacing of the reflection points 322 in the circumferential direction becomes larger, the number of reflection points 322 on the concentric circle is less. The brightness above the chip can be effectively modulated through the reflection patterns 300, thereby improving the light emitting uniformity of the LED lamp panel.

As one of the optional solutions, the air gap may include a hollodwed-out ring group, which includes a plurality of hollowed-out rings disposed concentrically, and there is a spacing between adjacent hollowed-out rings; The hollowed-out ring can be a circular ring or a polygonal ring. The spacings between adjacent hollowed-out rings may be equal, or the spacing near the center of the hollowed-out ring group may be larger than the spacing far away from the center of the hollowed-out ring group, so as to modulate the brightness above the LED chip 1, reinforce the brightness around the LED chip 1, and make the lighting effect uniformity better.

As one of the optional solutions, the reflection area includes strip-shaped reflection bands and reflection points, and the reflection points are located at the periphery of the reflection bands, that is, the area near the center of the LED chip 1. In the circumferential direction, the reflection bands are distributed in a continuous strip shape, and in the peripheral area of the LED chip 1, the reflection points can be distributed at intervals in the circumferential direction. Each LED chip 1 is correspondingly provided with the reflection bands right in front of the light emitting direction. A plurality of reflection bands are disposed, and the reflection bands can be disposed at intervals or/and intersected. The reflection points are circular or polygonal to modulate the brightness above the LED chip 1, reinforce the brightness around the LED chip 1, and make the uniformity of the lighting effect better.

In the specific application, the reflection points are evenly distributed, or the area of the reflection points decreases with the distance from the center of the reflection pattern, which is beneficial for reinforcing the brightness around the LED chip 1 and making the lighting effect more uniform.

In a specific application, the reflection units 320 include a plurality of reflection points around the center of the reflection pattern 300.

In specific applications, the encapsulant layer 130 may be a transparent glue layer to avoid light loss.

Specifically, the thickness of the encapsulant layer 130 may be 200 μm to 400 μm, and the light has a certain reflection distance and space, which is beneficial for improving the lighting effect.

In specific applications, as shown in FIG. 12, the sidewalls of the reflection units 320 can be optionally provided with demoulding inclined planes 131, which is convenient for demoulding the screen and is beneficial for improving the yield of products.

In specific applications, the reflection units may be a plurality of reflection blocks in a shape of blocks, and the area of each reflection block can be reduced in the direction away from the center of the LED chip 1. The closer each reflection block is to the LED chip 1, the larger its single area is. That is, as shown in FIG. 14, the reflection block includes a central block 327 close to the LED chip 1 and peripheral blocks 328 located at the periphery of the central block 327, and the size of the central block 327 is larger than that of the central blocks 327, so as to effectively modulate the brightness above the LED chip 1, reinforce the brightness at the periphery of the LED chip 1, and make the lighting effect uniform. In the specific application, as an alternative, the reflection block includes a central block 327 close to the LED chip 1 and a peripheral block 328 located around the central block 327. The reflectivity of the central block 327 is greater than that of the peripheral block 328. The central block 327 can be provided with titanium dioxide particles, and the peripheral block 328 can be provided with silicon dioxide particles. The central block 327 can be larger than or equal to the size of the peripheral block 328, so as to effectively modulate the brightness above the LED chip 1, reinforce the brightness around the LED chip 1, and make the light effect uniform.

In specific applications, as shown in FIGS. 10, 11 and 14, the reflectivity of the reflection units 320 in the central area of the reflection pattern 300 is greater than that of the reflection units 320 in the peripheral area of the reflection pattern 300. The reflection units 320 in the central region of the reflection pattern 300 contain titanium dioxide particles, and the reflection units 320 in the peripheral region of the reflection pattern 300 contain silicon dioxide particles. The part of the reflection area close to the LED chip 1 may be provided with titanium dioxide particles, and the part of the reflection area far away from the LED chip 1 may be provided with silicon dioxide particles.

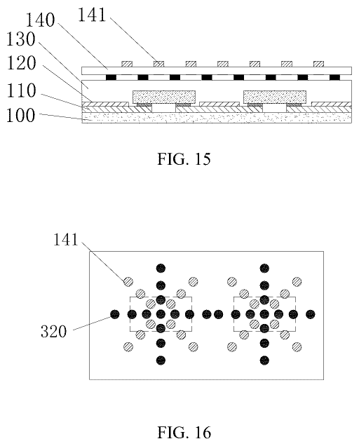

In another embodiment, the LED lamp panel of the present application may further include a second reflection layer. Referring to FIGS. 15 and 16, the present application provides an LED lamp panel, which includes a substrate 6, a circuit layer 3 and a plurality of LED chips 1. The circuit layer 3 is disposed on the substrate 6, and the LED chips 1 are disposed on the circuit layer 3 and electrically connected with the circuit layer 3. The LED lamp panel further includes a first reflective layer 131, which includes a first encapsulant layer 130 and a first reflection pattern 300 disposed on the upper surface of the first encapsulant layer 130. The first encapsulant layer 130 covers the substrate 6 and the plurality of LED chips 1. The first reflection pattern 300 includes a plurality of first reflection units 320 arranged at intervals, and air gaps 310 are formed between first reflection units 320. The LED lamp panel further includes a second reflection layer 140 disposed on the first reflective layer 131. The second reflection layer 140 includes a transparent second encapsulant layer 142 and a second reflection unit 141 for allowing some light rays to pass through. One side of the second encapsulant layer 142 covers the first reflective layer 131, and the second reflection unit 141 is disposed on second encapsulant layer 142.

The projection of the air gap 143 of the second reflection units 141 and that of the air gap of the reflection units 320 on the substrate 6 at least partially overlaps, and the light of the LED chip 1 can be modulated by two or more layers of reflection, which is beneficial for improving the uniformity of light emission. The material and thickness of the second reflection layer and the first reflection pattern 300 may be the same.

As shown in FIG. 15 and FIG. 16, second reflection layers 140 may be disposed on the first encapsulant layer 130 and the first reflection unit 320, and a plurality of reflection patterns of the second reflection units 141 may be disposed on the surface of the second reflective layer 140. The second reflection units 141 of the second reflection layer 140 and the first reflection units 320 can be staggered, and part of light will be reflected back and forth between the staggered second reflection units 141 and the first reflection units 320 and then is emitted out, which is beneficial for light uniformity. The second reflection unit 141 may have the same structure as the first reflection pattern 320, that is, it includes resin and reflective particles dispersed in the resin.

In the above embodiment, the reflection pattern can also be disposed on a single encapsulant layer and then pasted on the encapsulant layer, so that reflection layers or optical films with different reflection patterns can be prefabricated, and a reflection layer or optical film with specific reflection patterns can be selected and pasted on the encapsulant layer according to the application effect. Moreover, the reflection layer or optical film may be replaced, which is flexible and convenient to use and has a wide application range. In addition, a first reflection unit and a second reflection unit may also be screen-printed on the front and back of the same reflection layer or optical film (that is, the first reflection unit and the second reflection unit share one optical film as a carrier without disposing two optical films). The first reflection unit and the second reflection unit may be arranged in a staggered manner, so that the optical film can be directly attached to the encapsulant when in use, which is flexible and convenient to use, wide in application range and low in cost.

This embodiment also provides a manufacturing method of the LED lamp panel, which is used for manufacturing the backlight lamp panel, which including that following step:
a substrate 6 is prepared;
a circuit layer 3 is disposed on the substrate 6;
a LED chip 1 is connected to the circuit layer 3, and a first reflective layer 120 may be disposed on the circuit layer 3;
the LED chip 1 and the first reflective layer 120 are covered with a first encapsulant layer 130;
first reflection patterns 300 for allowing part of light to pass through and reflecting part of light are disposed on the first encapsulant layer 130 such that the reflection surface of the first reflection patterns 300 faces the light-emitting surface of the LED chip 1. Part of the light emitted by the LED chip 1 is emitted to the reflection area, and part of it directly penetrates through the air gap. The light emitted to the reflection area is reflected by the reflection area to form reflected light, part of the reflected light is reflected by the first reflective layer 120 and emitted from the air gap at the periphery of the LED chip 1 and the side surface, and part of the reflected light is reflected and emitted from the side surface of the light emitting chip 210. According to the characteristics of strong light emission at the center of the LED chip 1 and weak light emission at the periphery, in this embodiment, a hollowed-out structure is formed on the first reflection pattern 300 to form an air gap, which can modulate the proportion and proportion of the air gap area, weaken the light intensity in the central area of the front face of the LED chip 1 and increase the light intensity in the lateral area of the LED chip 1, so that part of the light emitted by the LED chip 1 can directly pass through the air gap and is emitted from the front face, while part of the light is reflected by the reflection area, which can effectively modulate the brightness above the LED chip 1 and ensure the lighting effect and brightness of the backlight board. At the same time, under the action of the first reflection pattern 300 and the first reflective layer 120, the light-emitting angle of the LED chip 1 is increased, and the brightness of the light-emitting around the LED chip 1 is improved, which has a good application effect.

Specifically, the first reflection pattern 300 is printed on the surface of the first encapsulant layer 130 by screen printing, and the process is simple and reliable, and the hollowing size, hollowing ratio, etc. can be accurately controlled, with a good product consistency, a high production efficiency and a low cost.

The LED lamp panel provided by the embodiment of the present disclosure is a backlight lamp panel. By disposing the first reflection patterns 300, part of the light emitted by the LED chip 1 can be emitted from the front of the first reflection pattern 300 through the air gap in front of the LED chip 1, while part of the light is emitted to the reflection area and reflected by the reflection area to form reflected light. Part of the reflected light is reflected by the first reflective layer 4 and then emitted from the air gap around the LED chip 1 and the side surface, while part of the reflected light is reflected and emitted from the side surface of the LED chip 1. In view of the characteristics of strong light emission at the center of the LED chip 1 and weak light emission at the periphery, in this embodiment, an air gap is formed by opening a hollowed-out structure on the first reflection pattern 300, so that the proportion and proportion of the air gap area can be modulated. Weakening the light intensity in the center area of the front of the LED chip 1 and increasing the light intensity in the lateral area of the LED chip 1 can make part of the light emitted by the LED chip 1 directly exit from the front through the air gap and part of it be reflected by the reflection area, which can effectively modulate the brightness above the LED chip 1 (that is, in front, right in front of the light-emitting direction) and ensure the lighting effect and brightness of the backlight board. At the same time, under the action of the first reflection patterns 300 and the first reflective layer 4, the light-emitting angle of the LED chip 1 is increased, and the brightness of the peripheral light of the LED chip 1 is improved, so that the light-emitting uniformity of the lamp panel is improved, and the application effect is good.

### Embodiment 3

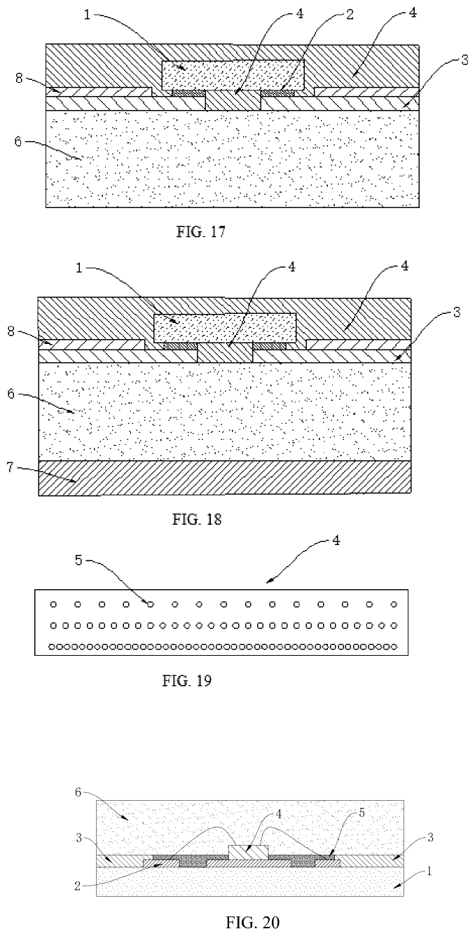

As shown in FIG. 17 and FIG. 18, an LED lamp panel provided by another embodiment of the present disclosure can be used for Mini LED backlight display modules and direct view products. The lamp panel includes a substrate 6, a first encapsulant layer 130, a circuit composite layer and LED chips 1. The circuit composite layer includes a circuit layer 3 and a first reflective layer 4, and the first reflective layer 4 is disposed on the circuit layer 3 and has a window structure. The first reflective layer 4 is disposed between the circuit layer 3 and the first encapsulant layer 130, and is provided with a plurality of window structures. The circuit layer 3 is disposed on one side of the substrate 6, and the circuit layer 3 has a bonding pad. The LED chips 1 are connected to the bonding pad. In this embodiment, the LED chip 1 is a flip chip, specifically a flip blue LED chip or a flip RGB LED chip set. The substrate 6 may be an FR4 circuit substrate or a glass substrate. The lamp panel further includes a second encapsulant layer 7, the first encapsulant layer 130 is disposed on one side of the substrate 6 and covers the LED chips 1 and the circuit layer 3, and the first encapsulant layer 130 allows the light emitted by the LED chip 1 to pass through. The second encapsulant layer 7 is disposed on the other side of the substrate 6 to partially or completely offset the stress generated by the first encapsulant layer 130 on the substrate 6.

It should be noted that if the first encapsulant layer 130 is formed by dispensing or molding, the first encapsulant layer 130 has a stress acting on the substrate 6, which makes the substrate 6 easy to deform, which is usually manifested as the two ends of the substrate 6 being warped and the middle part thereof being concave, causing the LED chips 1 to be easily peeled off. In this embodiment, the first encapsulant layer 130 and the second encapsulant layer 7 are respectively disposed on two sides of the substrate 6, and a sandwich structure is formed with the substrate 6 through the first encapsulant layer 130 and the second encapsulant layer 7. The first encapsulant layer 130 has a tensile stress acting on the substrate 6 and facing one side of the substrate 6, and the second encapsulant layer 7 has a tensile stress acting on the substrate 6 and facing the other side of the substrate 6, so that the tensile stress acting on both sides of the substrate 6 can be offset to a great extent. The warpage and deformation in the substrate 6 (especially the substrate 6) caused by the stress exerted by the encapsulant layer are effectively reduced, the problems of delamination, deformation, poor air tightness, and the like of the lamp panel after encapsulation are effectively improved, and adverse risks such as peeling of the LED chip 1 are avoided. Moreover, the first encapsulant layer 130 and the second encapsulant layer 7 form a sandwich structure with the substrate 6, without the need of multiple encapsulant layers, therefore the manufacturing process is simple and the cost is low.

In specific applications, the projection area of the first encapsulant layer 130 on the substrate 6 can cover the substrate 6, that is, the first encapsulant layer 130 can completely cover the surface of one side of the substrate 6. Alternatively, the first encapsulant layer 130 can be composed of first unconnected segmented glue layers, and the first encapsulant is molded on one side of the substrate 6 (specifically, one side of the circuit layer 3 and the top of the LED chip 1) by glue dispensing to form a plurality of unconnected first segmented glue layers. In another embodiment, the second encapsulant layer 7 may also be composed of second unconnected segmented glue layers, and the second encapsulant is molded on the other side of the substrate 6 by glue dispensing to form a plurality of segments of the second unconnected segmented glue layers, so as to offset the stress between the substrates 6 located on the two sides of the segmented glue layers and prevent the substrate 6 from being deformed. As an alternative embodiment, the first encapsulant layer 130 can completely cover one side of the substrate 6, and the second encapsulant layer 7 can partially cover the other side of the substrate 6, so that the back of the substrate 6 can reserve space for installing other components.

In specific applications, the thickness of the first encapsulant layer 130 is not less than the thickness of the second encapsulant layer 7. Specifically, the first encapsulant layer 130 located on one side of the substrate 6 can protect the LED chip 1 and requires a certain thickness. The second encapsulant layer 7 located on the other side of the substrate 6 has an additional thickness, which will increase the overall thickness of the product, which is not in line with the market trend of the overall thinning of LED modules. By controlling the thickness of the second encapsulant layer 7 to be smaller than that of the first encapsulant layer 130, it is beneficial for the overall thinning of the lamp panel and the miniaturization of the device, which can meet the market demand.

In specific applications, the thickness of the first encapsulant layer 130 is greater than that of the second encapsulant layer 7. The first encapsulant layer 130 has a first thermal expansion coefficient, and the second encapsulant layer 7 has a second thermal expansion coefficient, which is greater than the first thermal expansion coefficient. The product of the thickness of the first encapsulant layer 130 and the first thermal expansion coefficient is A, and the product of the thickness of the second encapsulant layer 7 and the second thermal expansion coefficient is B, where A is equal to or about equal to B. It should be explained that the thickness of the first encapsulant layer 130 is relatively large and the first thermal expansion coefficient is relatively small, while the thickness of the second encapsulant layer 7 is relatively small and the first thermal expansion coefficient is relatively large, so that the stresses acting on both sides of the substrate 6 can be balanced and offset. At the same time, the first encapsulant layer 130 can have a certain thickness to protect the LED chip, while the thickness of the second encapsulant layer 7 can be relatively small, which is beneficial for the thinning of the lamp panel. As another embodiment, the thickness of the first encapsulant layer 130 is equal to that of the second encapsulant layer 7, the e first encapsulant layer 130 has a first thermal expansion coefficient and the second encapsulant layer 7 has a second thermal expansion coefficient, which is the same as the first thermal expansion coefficient. In specific application, the most important parameters of the stress of the encapsulant layer on the substrate 6 are the thickness and thermal expansion coefficient of the encapsulant layer. In specific application, encapsulant materials with different thermal expansion coefficients can be selected according to the thickness of the encapsulant layer, and the regulation and control is flexible, so that the stress acting on both sides of the substrate 6 can be offset and the whole product tends to be thinner.

Further, the first encapsulant layer 130 and the second encapsulant layer 7 are made of the same material, both of which are epoxy resin or silicone resin, which is beneficial for reducing the cost. In another embodiment, the materials of the first encapsulant layer 130 and the second encapsulant layer 7 may also be different. The first encapsulant layer 130 is dispersedly provided with inorganic light-transmitting particles 5 for adjusting its thermal expansion coefficient, and the thermal expansion coefficient of the encapsulant layer can be adjusted by adding the inorganic light-transmitting particles into the encapsulant layer, so that the adjustment is convenient and the cost is low. The settling of the inorganic light-transmitting particles 5 in the first encapsulant layer 130 makes the content of the inorganic light-transmitting particles 5 gradually decrease along the direction away from the substrate 6, that is, the added inorganic light-transmitting particles 5 naturally settle in the first encapsulant, and the closer the area is to the substrate 6, the smaller its thermal expansion coefficient, which can effectively reduce the deformation of the substrate 6. The particle size of the inorganic light-transmitting particles 5 ranges from 50 nm to 5 μm. Inorganic light-transmitting particles 5 can transmit light, which is beneficial for ensuring the light emission of LED chips. In this embodiment, the inorganic light-transmitting particles 5 are silica powder or alumina powder, or a mixture of silica powder and alumina powder, and the inorganic light-transmitting particles 5 are added into the first encapsulant layer 130. In this embodiment, it is preferable that the particle size of the inorganic light-transmitting particles 5 ranges from 100 nm to 1 μm, and silica is the main component of glass, alumina is the main component of sapphire, silica powder and alumina powder are light-transmitting particles, and the doping ratio of silica powder or alumina powder in the first encapsulant layer 130 is 20% to 60%. By controlling the standing time of the first encapsulant before curing, the silica powder or alumina powder naturally settles in the first encapsulant and presents a stepped distribution, so that the closer to the substrate 6, the higher its content, that is, the smaller its thermal expansion coefficient, which further reduces the deformation of the substrate 6. In addition, the projection area of the encapsulant layer located at the other side of the substrate 6 on the substrate 6 can be flexibly adjusted, and it may not cover the other side of the substrate 6 completely due to cost factors; the adoption of light-transmitting particles does not affect the light emission of the LED chip 1, and the thermal expansion coefficient is adjusted, so that the adjustment effect is good and the cost is low.

As an alternative embodiment, the thickness of the first encapsulant layer 130 ranges from 150 μm to 400 μm; the thickness of the second encapsulant layer 7 ranges from 20 μm to 200 μm. In specific applications, the thickness of the first encapsulant layer 130 is not less than that of the second encapsulant layer 7, and the thickness of the first encapsulant layer 130 is preferably in the range of 250 μm to 300 μm. The first encapsulant layer 130 may be made of epoxy resin or silicone resin, and the second encapsulant layer 7 may also be made of either epoxy resin or silicone resin.

Further, as shown in FIG. 17 and FIG. 18, there is at least one pair of bonding pads in the corresponding area of each window structure, the LED chips 1 are disposed in the window structure and connected to the bonding pads in the corresponding window structure. The first encapsulant layer 130 is in direct contact with the substrate through the window structure. Specifically, the first encapsulant layer 130 includes an outer encapsulant layer located at the outer periphery of the LED chip 1 and a bottom encapsulant layer located at the window structure. The bottom encapsulant layer is formed by filling the window structure with the first encapsulant and is directly connected with the substrate 6, which is not only beneficial for die bonding, but also improves the lighting effect, backlight brightness, process yield and low manufacturing cost.

An embodiment of the present disclosure also provides a manufacturing method of an LED lamp panel, which is used for manufacturing the above LED lamp panel, which includes the following steps:
a substrate 6 is prepared, which may be a FR4 circuit substrate or glass substrate.

A circuit layer 3 with bonding pads is disposed on the substrate 6. In specific application, a first reflective layer 4 is also disposed above the circuit layer 3. The first reflective layer 4 is disposed in other areas of the circuit layer except the bonding pads, which has the function of insulation and oxidation prevention. The first reflective layer 4 is generally made of ink, white ink when applied to backlight products, and black ink when applied to direct view products.

The LEDs chip 1 are connected to the bonding pads; in the specific application, the solder paste layer 2 can be disposed on the bonding pad for facilitating welding.

As shown in FIG. 17, a first encapsulant layer 130 made of a first encapsulant is provided on one side of the substrate 6 to cover the LED chip 1 and the circuit layer 3.

Specifically, the first encapsulant is disposed on one side of the substrate 6 by dispensing or molding, and cured to form the first encapsulant layer 130.

As shown in FIG. 18, a second encapsulant layer 7 made of a second encapsulant is provided on the other side of the substrate 6. Specifically, the second encapsulant is disposed on the other side of the substrate 6 by dispensing or molding to form the second encapsulant layer 7. The first encapsulant layer 130 and the second encapsulant layer 7 form a sandwich structure with the substrate 6, so that the tensile stress acting on both sides of the substrate 6 is offset to a great extent, effectively reducing the warping deformation in the substrate 6 (especially the substrate 6) caused by the stress exerted by the encapsulant layer, and effectively improving the problems of delamination, deformation and poor air tightness of the lamp panel after encapsulation, and avoiding the bad risks such as peeling off of the LED chip 1

According to the LED lamp panel and the manufacturing method thereof provided by the embodiment of the present disclosure, the first encapsulant layer 130 is disposed on one side of the substrate 6 and covers the LED chip 1 and the circuit layer 3, the second encapsulant layer 7 is disposed on the other side of the substrate 6, and a sandwich structure is formed with the substrate 6 through the first encapsulant layer 130 and the second encapsulant layer 7, so that the stress acting on both sides of the substrate 6 can be offset to a great extent. The problems such as warping and deformation of the substrate 6 caused by stress are effectively reduced, delamination, deformation and poor air tightness of the lamp panel after encapsulation are effectively improved, adverse risks such as peeling of the LED chip 1 are avoided, and the production cost is low.

### Embodiment 4

As shown in FIG. 20 to FIG. 23, an LED lamp panel provided by an embodiment of the present disclosure includes a substrate 6, a circuit composite layer 3 a LED chip 4 and a second reflective layer 5. The circuit composite layer 3 is disposed on the substrate 6, and includes a circuit layer 2 and a first reflective layer 4 that has at least one window structure. The first reflective layer 4 is disposed on the circuit layer 2. Specifically, the reflective layer 4 is located at the top and the periphery of the circuit layer 2 and at least partially covers the peripheral edge of the circuit layer 2. The LED chip 1 is located in the window structure and connected to the circuit layer 2. In specific applications, there may be a plurality of LED chips 1, and the first reflective layer 4 may be correspondingly provided with a plurality of window structures, and each window structure is provided with one LED chip 1. The second reflective layer 5 is a colored glue layer, and is filled in the window structure of the first reflective layer 4, and the second reflective layer 5 is respectively connected with the LED chip 1 and the first reflective layer 4. Specifically, the second reflective layer 5 can be connected with the periphery of the LED chip 1, and the side surface of the second reflective layer 5 can be connected with the first reflective layer 4, as shown in FIG. 20.

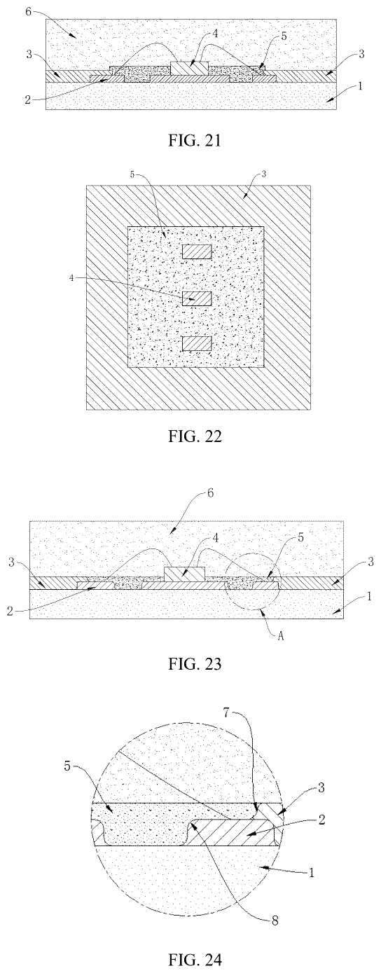

In another embodiment, the second reflective layer 5 can partially cover the top of the first reflective layer 4, as shown in FIG. 21. The color of the second reflective layer 5 is the same as that of the first reflective layer 4. Specifically, in one embodiment, when the LED lamp panel is used for white LED products, the second reflective layer 5 is a white glue layer, which can partially cover the circuit layer 2 around the LED chip 1 by disposing the white glue layer in the window structure. When the LED chip 1 emits light, by disposing the white glue layer around the LED chip 1, the reflectivity of the surrounding area of the LED chip 1 is improved, and the reflection effect is improved, so that the luminous brightness of the white LED product is improved, without the need of changing the size of the lamp bead and the size of the LED chip 1, and the brightness of the white LED can be effectively improved without improving the luminous efficiency of the chip, with a good improvement effect and a low cost.

In another embodiment provided by the present disclosure, the LED lamp panel is used in an RGB-LED direct view product, the second reflective layer 5 is a black glue layer. The blackness of the black glue layer can be adjusted to ensure that the blackness is sufficiently matched with the blackness of the reflective layer, so that the light reflection around the RGB-LED chip 1 is reduced, and the contrast can be effectively improved. In other embodiments, the LED lamp panel is used for monochromatic LED products, and the second reflective layer 5 is a colored glue layer with a color system corresponding to the color of the first reflective layer. For example, if the LED lamp panel is a red LED product, the second reflective layer 5 is a red glue layer, so that it is not mixed with other variegated colors to ensure the light purity. Of course, the LED lamp panel can also be other monochromatic LED products such as blue and green, and the second reflective layer 5 is correspondingly set as a blue glue layer and a red glue layer.

According to the LED lamp panel provided by the embodiment of the present disclosure, except that the top of the LED chip 1 is exposed from the substrate 6, the second reflective layer 5 with the same color as the first reflective layer 4 can completely cover the rest area of the substrate 6, that is, the second reflective layer 5 is disposed in the window structure, and can also cover the surrounding area of the LED chip 1, so that the surface color consistency of the encapsulated substrate can be effectively improved. Different colored colloids can be applied to improve the luminous brightness or contrast according to different occasions. In specific applications, when used in white LED products, a white glue layer can be used to enhance the reflective effect of the area around the LED chip 1 and effectively improve the brightness of white light; when used in RGB-LED direct view products, a black glue layer can be used to reduce the reflection of the area around the RGB-LED chip, reduce the reflection effect and effectively improve the contrast; when used in monochromatic LED products, a second reflective layer 5 corresponding to the color system is adopted, which can prevent the light emitted by the LED chip 1 from mixing with other miscellaneous colors and ensure the light purity.

Further, the upper end of the second reflective layer 5 and the upper end of the first reflective layer 4 are both lower than the upper end of the LED chip 1, the top of the LED chip 1 is exposed, and a large enough area for reflecting the light emitted by the LED chip 1 is formed around the LED chip 1. The second reflective layer 5 can be higher than the first reflective layer 4 and lower than the LED chip 1, that is, the top of the second reflective layer 5 can be located between the top surface of the first reflective layer 4 and the top surface of the LED chip 1.

Further, the thickness of the first reflective layer 4 ranges from 20 μm to 50 μm. In this embodiment, the thickness of the first reflective layer 4 is 30 μm. In specific applications, the first reflective layer 4 and the window structure can be molded at the same time (by an etching process). The first reflective layer 4 is formed by curing solder resist ink.

Further, the LED lamp panel further includes an encapsulant layer 6 that is disposed on the top of the first reflective layer 4 and the top of the second reflective layer 5 and covers the LED chip 1. Specifically, the encapsulant layer 6 covers the LED chip 1, and covers wires (gold wires) used for connection between the LED chip 1 and the circuit layer 2. The encapsulant layer 6 can be a transparent glue layer, and the transparent glue layer is formed by transparent glue encapsulation. According to the embodiment provided by the present disclosure, the display screen lamp beads can improve the brightness of products under the condition of sealing a transparent glue, or the visual effect of the lamp beads is completely black under the condition of sealing a transparent glue to greatly improve the contrast.

Furthermore, the second reflective layer 5 is made of the same material as the encapsulant layer 6, which can avoid the gap or repulsion of the contact part due to different materials, and the attachment at the joint is more fitted. Both the second reflective layer 5 and the encapsulant layer 6 can be made of epoxy resin, and in another embodiment, they may also be made of silica gel, which has a low cost and a good stability.

Further, the second reflective layer 5 is made of colored ink or colored colloid with a viscosity less than 2000 mPa·S. Specifically, the second reflective layer 5 is formed by solidification of colored colloid. The viscosity of colored colloid is the key, which affects its fluidity. The colored colloid is sprayed on the functional area around the LED chip 1 (that is, the window structure), and the viscosity range of the colored colloid is 0-2,000 mPa·S. Under the liquid surface tension and capillary action of the colored colloid, the colored colloid is evenly spread on the bottom surface of the lamp bead. By controlling the amount of colored colloid, after the colored colloid is cured, the bottom of the substrate 66 (PCB substrate in this embodiment) is covered with colored colloid except the LED chip 1, and the color of the functional area changes with the color of the colored colloid.

Further, as shown in FIG. 23 and FIG. 24, the inner sidewall of the window structure or the circuit layer has a fillet or chamfer structure. Specifically, in this embodiment, the lower and upper ends of the inner sidewall of the window structure have a fillet structure 7, and the fillet structure 7 may also be replaced by a chamfer structure, so that the second reflective layer 5 can be better combined with the inner sidewall of the window structure to avoid bubbles and cavities. Specifically, the inner sidewall of the circuit layer 3 may also have a fillet structure 8. The inner sidewall of the window structure can have any one of a curved surface, an inclined surface or a rough surface, and the lower end and the upper end of the inner sidewall of the window structure extend in mutually opposite directions to ensure that there is no gap between the second reflective layer 5 formed by filling colored colloid and the inner sidewall of the window structure. There are a plurality of window structures, and one or more LED chips 1 are wire-bonded chips or flip chips and are fixed in each window structure. The LED lamp panel can be applied to traditional lamp beads and mini COB products.

An embodiment of the present disclosure also provides a manufacturing method for manufacturing the above LED lamp panel, which includes the following steps:
a substrate 6 is prepared, wherein the substrate 6 is a PCB substrate;
a circuit layer 2 is disposed on the substrate 6;
a first reflective layer 4 is disposed on the substrate 6, and the first reflective layer 4 has a window structure, which can be specifically formed by an etching process; the first reflective layer 4 is located at the outer periphery of the circuit layer 2 and at least partially covers the outer peripheral edge of the circuit layer 2; in specific applications, the first reflective layer 4 and the window structure can be formed simultaneously; more specifically, the thickness of the first reflective layer 4 ranges from 20 μm to 50 μm;
an LED chip 1 is disposed in the window structure and is connected with the circuit layer 2; in specific applications, the connection between the LED chip 1 and the circuit layer 2 can be realized by wires (gold wires);
colored colloid or colored ink with the same color as the first reflective layer 4 is filled into the window structure to form a second reflective layer 5, which is respectively connected with the LED chip 1 and the first reflective layer 4; in this embodiment, the second reflective layer 5 may be in contact with the outer periphery of the LED chip 1; in an embodiment, the side surface of the second reflective layer 5 is in contact with the first reflective layer 4, or in another embodiment, the second reflective layer 5 may partially cover the top of the first reflective layer 4.

According to the LED lamp panel and the manufacturing method thereof provided by the embodiment of the present disclosure, except that the LED chip 1 is exposed out of the substrate 6, the second reflective layer 5 with the same color as the first reflective layer 4 is respectively connected with the LED chip 1 and the first reflective layer 4, and the second reflective layer 5 can completely cover the rest area of the substrate 6, that is, the second reflective layer 5 may be filled in the window structure, and may also cover the surrounding area of the LED chip 1, so that the surface color consistency of the encapsulated substrate can be effectively improved. Colloids with different colors can be applied to improve the luminous brightness or contrast according to different occasions. When the LED encapsulation structure is used for white LED products, the white glue layer can enhance the reflective effect of the area around the LED chip 1, thus effectively improving the white brightness. When the LED encapsulation structure is used in RGB-LED direct view products, the black glue layer can reduce the reflection of the area around the RGB-LED chip, reduce the reflection effect and effectively improve the contrast. When the LED encapsulation structure is used for monochromatic LED products, the second reflective layer 5 with a color system corresponding to the color of the reflective layer is adopted, which can prevent the light emitted by the LED chip 1 from mixing with other miscellaneous colors and ensure the light purity.

The above embodiments are only preferred embodiments of the present disclosure, and they are not intended to limit the present disclosure. Any modification, equivalent substitution or improvement made within the spirit and principle of the present disclosure shall fall within the protection scope of the present disclosure.

What is claimed is:

1. An LED lamp panel, comprising:
a substate;
a plurality of LED chips; and
a circuit composite layer disposed on the substrate;
wherein the circuit composite layer comprises a circuit layer and a first reflective layer with a plurality of window structures, the first reflective layer is disposed on the circuit layer, and the plurality of LED chips are respectively disposed in the window structures and electrically connected to the circuit layer; and
wherein a second reflective layer is filled in the window structures, covering the LED chips and the circuit composite layer, and is connected with the first reflective layer; and the second reflective layer has a color identical with that of the first reflective layer.

2. The LED lamp panel according to claim 1, wherein the second reflective layer is disposed in an accommodating area formed between an outer periphery of the plurality of LED chips and an inner periphery of the window structure, and the second reflective layer contains reflective particles.

3. The LED lamp panel according to claim 2, wherein the plurality of LED chips are flip chips, and the second reflective layer is disposed in a gap between a side of the plurality of LED chips facing the substrate and the substrate.

4. The LED lamp panel according to claim 2, wherein a surface of the circuit composite layer is provided with a solder paste layer configured for connecting with the LED chip, and the second reflective layer covers the periphery of a joint between the LED chip and the solder paste layer.

5. The LED lamp panel according to claim 2, wherein a height of a light-emitting surface of the LED chip is greater than or equal to that of the first reflective layer, and a height of a top surface of the second reflective layer is less than or equal to that of a top surface of the first reflective layer.

6. The LED lamp panel according to claim 2, wherein the second reflective layer has a reflectivity greater than that of the first reflective layer.

7. The LED lamp panel according to claim 2, wherein the first reflective layer is made of white ink.

8. The LED lamp panel according to claim 2, wherein a value of a thickness of the first reflective layer ranges from 20 μm to 80 μm.

9. The LED lamp panel according to claim 2, wherein the dimensions of the window structure satisfy the following relationship:
Bx<Px, By<Py;
where Bx represents the largest dimension of the window structure in the transverse direction, By represents the largest dimension of the window structure in the longitudinal direction, Px represents the transverse spacing between two adjacent LED chips, and Py represents the longitudinal spacing between two adjacent LED chips.

10. The LED lamp panel according to claim 9, wherein the window structure is a rectangular through hole, and a length dimension of the rectangular through hole is greater than or equal to ≥2 mm.

11. An LED lamp panel, comprising:
a substrate and a plurality of LED chips, wherein a circuit composite layer is disposed on the substrate, and the circuit composite layer comprises bonding pads for connecting with the plurality of LED chips; and
an encapsulant layer covering the substrate and the LED chips, wherein an upper surface of the encapsulant layer is provided with a plurality of reflection patterns;
wherein the reflection pattern comprises a plurality of reflection units disposed at intervals, and a density of the reflection units in a central area of the reflection pattern is greater than that in a peripheral region of the reflection pattern.

12. The LED lamp panel according to claim 11, wherein in one of the reflection patterns, an area of the air gap accounts for 20% to 80% of an area of an outline of the reflection pattern, and the reflection pattern has a thickness of 10 μm to 60 μm.

13. The LED lamp panel according to claim 11, wherein the reflection units comprise a reflection ring located in the central area of the reflection pattern.

14. The LED lamp panel according to claim 13, wherein the reflection units comprise a plurality of reflection rings disposed concentrically, and a gap is between adjacent reflection rings.

15. The LED lamp panel according to claim 14, wherein the periphery of the reflection ring is provided with reflection points, and a distribution density of the reflection points decreases with a distance from the center of the reflection pattern.

16. The LED lamp panel according to claim 11, wherein the reflection units comprise a plurality of reflection points around the center of the reflection pattern, and areas of the reflection points decrease with a distance from the center of the reflection pattern.

17. The LED lamp panel according to claim 11, wherein a reflectivity of the reflection units in the central area of the reflection pattern is greater than that of the reflection units in a peripheral area of the reflection pattern.

18. The LED lamp panel according to claim 11, wherein the reflection units in the central area of the reflection pattern contain titanium dioxide particles, and the reflection units in the peripheral area of the reflection pattern contain silicon dioxide particles.

19. The LED lamp panel according to claim 11, wherein the reflection pattern is formed by screen printing, and sidewalls of the reflection units are provided with demoulding inclined planes.

20. The LED lamp panel according to claim 11, further comprising a second reflection layer disposed above the second reflective layer, wherein diffusion patterns are printed on a surface of the second reflection layer, and the diffusion patterns of the second reflection layer and the reflection patterns are disposed in a staggered manner.
